(19) United States
(12) Patent Application Publication
(10) Pub. No.: US 2009/0296330 A1
(43) Pub. Date: Dec. 3, 2009

(54) ELECTRONIC APPARATUS

(75) Inventors: Kwun-Yao Ho, Taipei Hsien (TW); Wen-Yuan Chang, Taipei Hsien (TW); Chen-Yueh Kung, Taipei Hsien (TW); Ming-Jen Lin, Taipei Hsien (TW)

Correspondence Address: J C PATENTS, 4 VENTURE, SUITE 250, IRVINE, CA, 92618, US

(73) Assignee: VIA TECHNOLOGIES, INC., Taipei Hsien (TW)

(21) Appl. No.: 12/433,447

(22) Filed: Apr. 30, 2009

(30) Foreign Application Priority Data
May 27, 2008 (EP) 08251832.5

(51) Int. Cl. G06F 1/16; H05K 7/00

(52) U.S. Cl. 361/679.4; 361/679.02

(57) ABSTRACT

An electronic apparatus including a main board, an input/output (I/O) board, and a flexible printed circuit (FPC) is provided. The main board includes a first carrier, a central processing unit (CPU), a north bridge unit, a south bridge unit, a basic input/output system (BIOS), a memory module, a clock generator, a graphic unit, and at least one power management. The CPU, the north bridge unit, the south bridge unit, the BIOS, the memory module, the clock generator, the graphic unit, and the power management are disposed on the first carrier. The I/O board includes a second carrier an I/O module and an I/O connector. The I/O module and the I/O connector are disposed on the second carrier. The FPC connects the first carrier and the second carrier.

### CROSS-REFERENCE TO RELATED APPLICATION

This application claims the priority benefit of European application serial no. 08251832.5, filed on May 27, 2008. The entirety of the above-mentioned patent application is hereby incorporated by reference herein and made a part of specification.

### BACKGROUND OF THE INVENTION

1. Field of the Invention

The present invention generally relates to an electronic apparatus and, in particular, to an electronic apparatus using a flexible printed circuit (FPC).

2. Description of Related Art

Computers such as personal computers (PC), notebook computers, tablet computers, etc. have been very popular nowadays. People access the internet to communicate with the world through computers, such that the transportation of information becomes faster. Computers change people's life styles and bring much convenience in daily lives.

A conventional PC includes a mother board, a plurality of system components, and a plurality of input/output (I/O) components. The system components and the I/O components are disposed on the mother board. The system components include a central processing unit (CPU), a chipset including north bridge and south bridge chips, a basic input/output system (BIOS), a memory module, a clock generator, a power management, etc. The I/O components include a video jack, an audio jack, universal system bus (USB) jacks, a keyboard jack, a mouse jack, etc. In some advanced PC, the mother board even includes I/O components such as wireless communication module, global positioning system (GPS) module, etc.

Generally speaking, the needs of the I/O functions of a mother board are various among different customers. For example, the keyboard jack and the mouse jack, such as personal system/2 (PS/2) jacks, may be necessary for some customers. However, for other customers, more USB jacks are needed to replace the keyboard jack and the mouse jack, such that the keyboard jack and the mouse jack are not needed. Since the system components and the I/O components are disposed on a single mother board, the designs of the mother board must be changed just due to the needs of the I/O components are different. In this way, the cost of the PC is increased, and the time to market is too long. If the designs of the mother board are not changed with different requirements of customers, some I/O components may be redundant and not used by user, which causes a waste of I/O components. In addition, the layout of a single mother board has less flexibility for matching various appearances of PCs.

### SUMMARY OF THE INVENTION

Accordingly, the present invention is directed to an electronic apparatus which has both a lower cost and more design flexibility.

According to an embodiment of the present invention, an electronic apparatus including a main board, an input/output (I/O) board, and a flexible printed circuit (FPC) is provided. The main board includes a first carrier, a central processing unit (CPU), a north bridge unit, a south bridge unit, a basic input/output system (BIOS), a memory module, a clock generator, a graphic unit, and at least one power management. The CPU, the north bridge unit, the south bridge unit, the BIOS, the memory module, the clock generator, the graphic unit, and the power management are disposed on the first carrier. The I/O board includes a second carrier at least one I/O module and at least one I/O connector. The I/O module and the I/O connector are disposed on the second carrier. The FPC connects the first carrier and the second carrier.

According to an embodiment of the present invention, an electronic apparatus including a main board, an input/output (I/O) board, and a flexible printed circuit (FPC) connecting the first carrier and the second carrier. The main board includes a first carrier; and a central processing unit (CPU) disposed on the first carrier. The input/output (I/O) board includes a second carrier, at least one I/O module disposed on the second carrier and at least one I/O connector disposed on the second carrier. The flexible printed circuit (FPC) includes a first conductive layer adapted to be electrically connected to ground, a first patterned conductive layer disposed above the first conductive layer, a second patterned conductive layer disposed above the first patterned conductive layer, a second conductive layer disposed above the second patterned conductive layer and adapted to be electrically connected to ground, and a plurality of insulating layers respectively disposed between two adjacent conductive layers.

In the electronic apparatus according to the embodiment of the present invention, the I/O board is connected to the main board through the FPC. When the requirements of I/O functions from different customers are different, only the designs of the I/O board are needed to be different, but the main board is the same and adapted to different requirements. In this way, the cost of the electronic apparatus is reduced.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic structural view of an electronic apparatus according to an embodiment of the present invention.

FIG. 2 is a schematic local cross-sectional view of the FPC in FIG. 1.

FIG. 3A is a simplified local cross-sectional view of the FPC in FIG. 1.

FIG. 3B is schematic local top view of the second conductive layer of the FPC in FIG. 2.

FIG. 4 is a schematic structural view of an electronic apparatus according to another embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

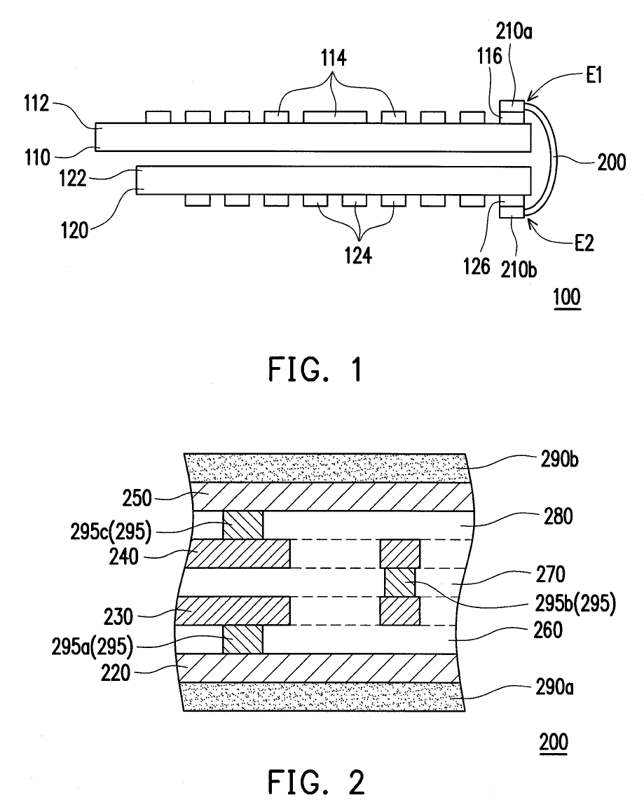

FIG. 1 is a schematic structural view of an electronic apparatus according to an embodiment of the present invention. Referring to FIG. 1, the electronic apparatus 100 of the present embodiment is, for example, a personal computer (PC), a notebook computer, a tablet computer, a personal digital assistant (PDA), a phone PC, or other appropriate electronic apparatus. The electronic apparatus 100 includes a main board 110. The main board 110 includes a first carrier 112 and a plurality of system components 114. In the present embodiment, the first carrier 112 is, for example, a circuit substrate. The system components 114 are disposed on the first carrier 112, and include a central processing unit (CPU), a north bridge unit, a south bridge unit, a basic input/output system (BIOS), a memory module, a clock generator, a graphic unit, at least one power management. Additionally, the system components 114 may further include a plurality of passive components, other IC components or other appropriate system components.

In the present embodiment, the CPU, the north bridge unit, the south bridge unit, the BIOS, the memory module, the clock generator, the graphic unit, and the power management are individual components. However, in other embodiments (not shown), at least two of the CPU, the north bridge unit, the south bridge unit, the BIOS, the memory module, the clock generator, the graphic unit, and the power management may compose a single combination chip. For example, (i) the single combination chip is composed of the north bridge unit and the south bridge unit and has multiple functions; (ii) the single combination chip is composed of the north bridge unit and the CPU and has multiple functions, and the south bridge unit is a individual chip; (iii) the single combination chip is composed of the north bridge unit, the south bridge unit, and the CPU and has multiple functions; (iv) the single combination chip is composed of the north bridge unit, the south bridge unit, and the power management and has multiple functions; (v) the single combination chip is composed of the north bridge unit, the south bridge unit, and the clock generator and has multiple functions; (vi) the single combination chip is composed of the north bridge unit, the south bridge unit, and the graphic unit and has multiple functions; (vii) the single combination chip is composed of the north bridge unit, the south bridge unit, the graphic unit, and the CPU and has multiple functions.

The electronic apparatus 100 further includes an input/output (I/O) board 120. The I/O board 120 includes a second carrier 122 and a plurality of I/O components 124. The second carrier 122 is, for example, a circuit substrate. The I/O components 124 are disposed on the second carrier 122. The I/O components 124 include at least one I/O connector and at least one I/O module. The I/O module of the present invention means at least one semiconductor component therein. The semiconductor component may be an electronic component that exploits the electronic properties of semiconductor materials, such as silicon, germanium, and gallium arsenide. Semiconductor component has replaced a thermionic device (such as vacuum tube) in most applications. Semiconductor component uses electronic conduction in the solid state as opposed to the gaseous state or thermionic emission in a high vacuum. The semiconductor component may be used as an active component or a passive component. The active component may be a transistor, a bipolar junction transistor (BJT), etc. The passive component may be a resistor, a capacitor, an inductor, a filter, etc. In the other embodiment of the present invention, the I/O components 124 further include a plurality of passive components.

In the present embodiment, the I/O connector of the I/O components 124 may be a video connector, an audio connector, universal system bus (USB) connector, a keyboard connector, a mouse connector, or other appropriate I/O connector. More particularly, the video connector, the audio connector, the USB connector, the keyboard connector, and the mouse connector may be a video jack, an audio jack, a USB jack, a keyboard jack, and a mouse jack, respectively. The I/O module of the I/O components 124 may be a wireless communication module, a global positioning system (GPS) module, or other appropriate I/O module. More particularly, the wireless communication module is, for example, a Wi-Fi module, a blue tooth module, a radio frequency (RF) module, or a combination of two or three of the Wi-Fi, blue tooth and RF modules, etc.

The electronic apparatus 100 further includes a flexible printed circuit (FPC) 200. The FPC 200 connects the first carrier 112 and the second carrier 122. In the present embodiment, the main board 112 further includes a first connector 116 disposed on the first carrier 112, and the I/O board 122 further includes a second connector 126 disposed on the second carrier 122. Moreover, in the present embodiment, the FPC 200 includes a third connector 210a at a first end E1 of the FPC 200 and a fourth connector 210b at a second end E2 of the FPC 200 opposite to the first end E1. The third connector 210a is connected to the first connector 116, and the fourth connector 210b is connected to the second connector 126. In this way, the main board 110 is electronically connected with the I/O board 120 through the FPC 200. Therefore, a signal from the system component 114 of the main board 110 will pass through the first connector 116 of the main board 110, the third connector 210a of the FPC 200, the FPC 200, the fourth connector 210b of the FPC 200 and the second connector 126 of the I/O board 120, and then be transmitted to the I/O board 122. On the other hand, a signal from the I/O board will pass through the second connector 126 of the I/O board 120, the fourth connector 210b of the FPC 200, the FPC 200, the third connector 210a of the FPC 200, the first connector 116 of the main board 110, and then be transmitted to the system component 114 of the main board 110.

In the electronic apparatus 100 of the present embodiment, the main board 110 and the I/O board 120 are individual boards and connected with each other through the FPC 200. When the requirements of the I/O functions from different customers are different, only a kind of I/O board 120 should be replaced by other kinds of I/O boards 120, but the main board 110 is the same and adapted to various requirements. Different kinds of the I/O boards 120 may have different I/O functions. For example, some customers don't need wireless communication modules for their electronic apparatus, such that wireless communication modules are not necessary to equip on the I/O board 120. Therefore, the size of the I/O boards 120 can be reduced and the cost can be down, too. In summary, the I/O components 124 equipped on the I/O board 120 can be chosen by customers' needs or requirements. The I/O board 120 can be customized. In this way, the cost of the electronic apparatus 100 is reduced because the main board 110 does not need to be replaced when the requirement of the I/O functions is changed and because the main board 110 does not need to be debugged every time the requirement of the I/O functions is changed. Additionally, the time to market of the electronic apparatus 100 is shortened because the main board 110 does not need to be redesigned and redebugged every time the requirement of the I/O function is changed. Moreover, since the FPC 200 is flexible, the layout of the main board 110 and the I/O board 120 has more flexibility for matching various appearances of the electronic apparatus 100. Furthermore, the horizontal layout area of the electronic apparatus 100 can be reduced because the main board 110 can overlap with the I/O board 120 through the FPC 200 in the vertical direction.

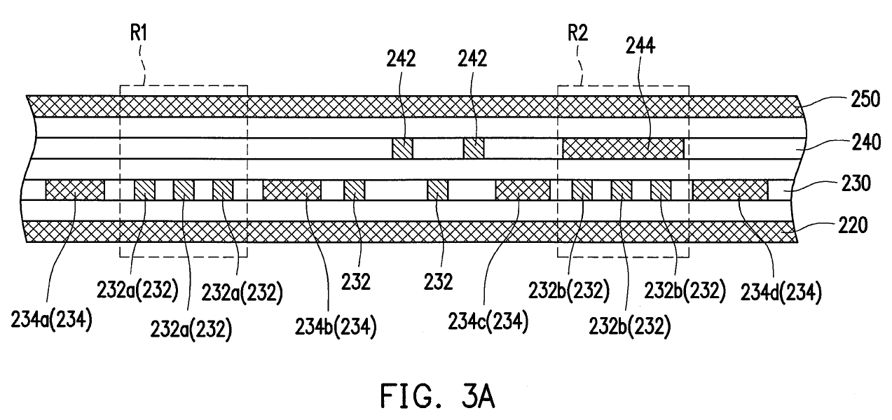

FIG. 2 is a schematic local cross-sectional view of the FPC in FIG. 1. Referring to FIG. 2, in the present embodiment, the FPC 200 includes a first conductive layer 220, a first patterned conductive layer 230, a second patterned conductive layer 240, and a second conductive layer 250. The material of the first conductive layer 220, a first patterned conductive layer 230, a second patterned conductive layer 240, and a second conductive layer 250 is, for example, metal or appropriate conductive nonmetal. The first patterned conductive layer 230 is disposed above the first conductive layer 220. The second patterned conductive layer 240 is disposed above the first patterned conductive layer 230. The second conductive layer 250 is disposed above the second patterned conductive layer 240. In particular, the FPC 200 further includes a first insulating layer 260, a second insulating layer 270, and a third insulating layer 280. The first insulating layer 260 is disposed between the first conductive layer 220 and the first patterned conductive layer 230. The second insulating layer 270 is disposed between the first patterned conductive layer 230 and the second patterned conductive layer 240. The third insulating layer 280 is disposed between the second patterned conductive layer 240 and the second conductive layer 250.

Additionally, in the present embodiment, the FPC 200 further includes two preservation layers 290a, 290b disposed on the first conductive layer 220 and the second conductive layer 250, respectively. The FPC 200 may further include a plurality of conducting vias 295, and each conducting via 295 electrically connects two conductive layers. For example, the conducting via 295a electrically connects the first conductive layer 220 and the first patterned conductive layer 230, the conducting via 295b electrically connects the first patterned conductive layer 230 and the second patterned conductive layer 240, and the conducting via 295c electrically connects the second patterned conductive layer 240 and the second conductive layer 250.

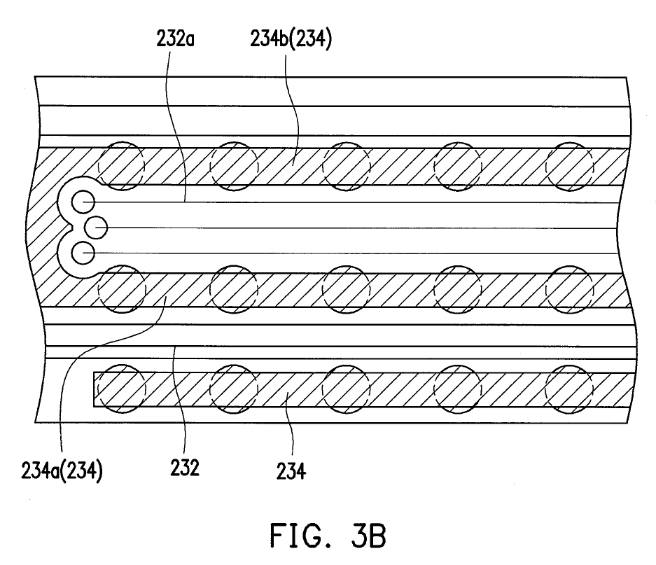

FIG. 3A is a simplified local cross-sectional view of the FPC in FIG. 1, and FIG. 3B is schematic local top view of the second conductive layer of the FPC in FIG. 2. Referring to FIGS. 3A and 3B, in the present embodiment, the first patterned conductive layer 230 includes a plurality of signal traces 232, and the second patterned layer 240 includes a plurality of signal traces 242. The signal traces 232 do not overlap the signal traces 242, which reduces the electromagnetic interference between the signal traces 232 and the signal traces 242. Additionally, in the present embodiment, the first conductive layer 220 and the second conductive layer 250 are adapted to be electrically connected to ground, which provides impedance control, ground guarding control, and electromagnetic interference shielding, such that the signal traces 232 and the signal traces 242 may carry differential pair signals and high speed signals.

In the present embodiment, the FPC 200 has a universal system bus (USB) region R1. The first patterned conductive layer 230 includes a plurality of first signal traces 232a and two ground guarding traces 234, such as ground guarding traces 234a and 234b. The first signal traces 232a are disposed within the USB region R1 and adapted to carry USB signals. The two ground guarding traces 234a and 234b are disposed at two opposite sides of the USB region R1, respectively. The second patterned conductive layer 240 has no conductive trace (such as metal trace) overlapping with the first signal traces 232a within the USB region R1 to prevent from signal interference and keeping high signal quality. The ground guarding traces 234 are adapted to be electrically connected to ground, which makes the first signal traces 232a carry high speed signals, differential pair signals, analogy signals, and have these signals with well control, and the signal quality can keep high.

In the present embodiment, the FPC 200 has a video signal region R2. The first patterned conductive layer 230 includes a plurality of second signal traces 232b and two ground guarding traces 234c and 234d. The second signal traces 232b are disposed within the video signal region R2 and adapted to carry video signals, such as RGB signals or other types of video signals. The two ground guarding traces 234c and 234d are disposed at two opposite sides of the video signal region R2, respectively. In the present embodiment, the second patterned conductive layer 240 includes a ground guarding trace 244. The orthogonal projections of the second signal traces 232b on the second patterned conductive layer 240 are located within the ground guarding trace 244. The ground guarding traces 234c, 234d and the ground guarding trace 244 are adapted to be electrically connected to ground, such that the second signal traces 232b can carry high speed signals and have these signals with well control, and the signal quality can keep high.

It should be noted that the first signal traces 232a and the second signal traces 232b are not limited to be located at the first patterned conductive layer 230. In other embodiments (not shown), the first signal traces 232a may be located at the second patterned conductive layer 240. Alternatively, the second signal traces 232b and the ground guarding trace 244 may be located at the second patterned conductive layer 240 and the first patterned conductive layer 230, respectively.

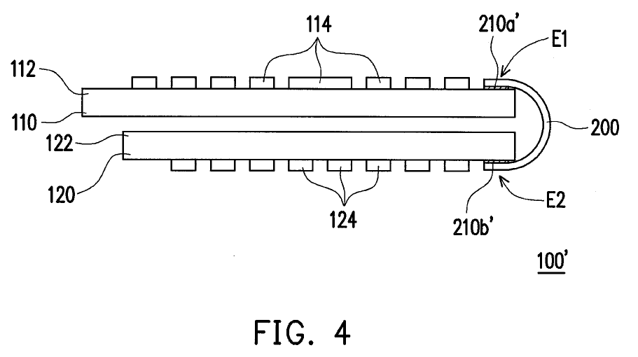

FIG. 4 is a schematic structural view of an electronic apparatus according to another embodiment (if the present invention. Referring to FIG. 4, the electronic apparatus 100′ of the present embodiment is similar to the above electronic apparatus 100 shown in FIG. 1, and the differences therebetween are as follows. The electronic apparatus 100′ includes a plurality of first finger pads 210a′ and a plurality of second finger pads 210b′. The first finger pads 210a′ connects the first carrier 112 and the first end E1 of the FPC 200, and the second finger pads 210b′ connects the second carrier 122 and the second end E2 of the FPC 200, such that the main board 110 is electrically connected with the I/O board 120 through the FPC 200.

To sum up, in the electronic apparatus according to the embodiments of the present invention, the main board and the I/O board are individual boards and connected with each other through the FPC. When the requirements of the I/O functions from different customers are different, only a kind of I/O board should be replaced by other kinds of I/O boards, but the main board is the same and adapted to various requirements. Different kinds of the I/O boards may have different I/O functions. In this way, the cost of the electronic apparatus is reduced because the main board does not need to be replaced when the requirement of the I/O functions is changed and because the main board does not need to be debugged every time the requirement of the I/O functions is changed.

Additionally, the time to market of the electronic apparatus is shortened because the main board does not need to be redesigned and redebugged every time the requirement of the I/O function is changed. Moreover, since the FPC is flexible, the layout of the main board and the I/O board has more flexibility for matching various appearances of the electronic apparatus. Furthermore, the horizontal layout area of the electronic apparatus can be reduced because the main board can overlap with the I/O board through the FPC in the vertical direction.

Moreover, the signals transmitted in the signal traces are protected by the ground guarding traces, the first conductive layer electrically connected to ground, and the second conductive layer electrically connected to ground, which makes the signal traces carry high speed signals, differential pair signals, analogy signals, and have these signals with well control, and the signal quality can keep high.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic apparatus, comprising:
a main board comprising:
a first carrier;
a central processing unit (CPU) disposed on the first carrier;
a north bridge unit disposed on the first carrier;
a south bridge unit disposed on the first carrier;
a basic input/output system (BIOS) disposed on the first carrier;
a memory module disposed on the first carrier;
a clock generator disposed on the first carrier;
a graphic unit disposed on the first carrier; and
at least one power management disposed on the first carrier; and
an input/output (I/O) board comprising:
a second carrier;
at least one I/O module disposed on the second carrier; and
at least one I/O connector disposed on the second carrier; and
a flexible printed circuit (FPC) connecting the first carrier and the second carrier.

2. The electronic apparatus according to claim 1, wherein the I/O module includes at least one semiconductor component.

3. The electronic apparatus according to claim 2, wherein the at least one semiconductor component is an active component or a passive component.

4. The electronic apparatus according to claim 1, wherein the FPC comprises:
a first conductive layer adapted to be electrically connected to ground;
a first patterned conductive layer disposed above the first conductive layer;
a second patterned conductive layer disposed above the first patterned conductive layer; and
a second conductive layer disposed above the second patterned conductive layer and adapted to be electrically connected to ground.

5. The electronic apparatus according to claim 4, wherein the FPC further comprises:
a first insulating layer disposed between the first conductive layer and the first patterned conductive layer;
a second insulating layer disposed between the first patterned conductive layer and the second patterned conductive layer; and
a third insulating layer disposed between the second patterned conductive layer and the second conductive layer.

6. The electronic apparatus according to claim 5, wherein the FPC has a universal system bus (USB) region, and the first patterned conductive layer comprises:
a plurality of first signal traces disposed within the USB region; and
two ground guarding traces respectively disposed at two opposite sides of the USB region, the ground guarding traces are adapted to be electrically connected to ground, wherein the second patterned conductive layer has no conductive trace overlapping the first signal traces within the USB region.

7. The electronic apparatus according to claim 5, wherein the FPC has a video signal region, and the first patterned conductive layer comprises:
a plurality of second signal traces disposed within the video signal region; and
two first ground guarding traces respectively disposed at two opposite sides of the video signal region, and
the second patterned conductive layer comprises a second ground guarding trace, wherein orthogonal projections of the second signal traces on the second patterned conductive layer are located within the second ground guarding trace.

8. The electronic apparatus according to claim 5, wherein the first patterned conductive layer comprises a plurality of first signal traces, the second patterned conductive layer comprises a plurality of second signal traces, and the first signal traces do not overlap the second signal traces.

9. The electronic apparatus according to claim 1, wherein the main board further comprises a first connector disposed on the first carrier, the I/O board further comprises a second connector disposed on the second carrier, the FPC comprises a third connector at one end of the FPC and a fourth connector at another end of the FPC opposite to the end, the third connector is connected to the first connector, and the fourth connector is connected to the second connector.

10. The electronic apparatus according to claim 9, wherein a signal from the main board passes through the first connector of the main board, the third connector of the FPC, the FPC, the fourth connector of the FPC and the second connector of the I/O board, and is then transmitted to the I/O board.

11. The electronic apparatus according to claim 9, wherein a signal from the I/O board passes through the second connector of the I/O board, the fourth connector of the FPC, the FPC, the third connector of the FPC, the first connector of the main board, and is then transmitted to the main board.

12. The electronic apparatus according to claim 1, wherein at least two of the CPU, the north bridge unit, the south bridge unit, the BIOS, the memory module, the clock generator, the graphic unit, and the power management compose a single combination chip.

13. The electronic apparatus according to claim 1, wherein the I/O board further comprises a wireless communication module disposed on the second carrier.

14. The electronic apparatus according to claim 13, wherein the wireless communication module includes a Wi-Fi module, a blue tooth module, a radio frequency (RF) module, or a combination of two or three of the Wi-Fi, blue tooth and RF modules.

15. The electronic apparatus according to claim 1, wherein the I/O board further comprises global positioning system (GPS) module disposed on the second carrier.

16. The electronic apparatus according to claim 1, wherein the I/O board further comprises a USB connector disposed on the second carrier.

17. An electronic apparatus, comprising:
a main board comprising:
a first carrier; and
a central processing unit (CPU) disposed on the first carrier; and
an input/output (I/O) board comprising:
a second carrier;
at least one I/O module disposed on the second carrier; and
at least one I/O connector disposed on the second carrier; and
a flexible printed circuit (FPC) connecting the first carrier and the second carrier, wherein the FPC comprises:
a first conductive layer adapted to be electrically connected to ground;
a first patterned conductive layer disposed above the first conductive layer;
a second patterned conductive layer disposed above the first patterned conductive layer;
a second conductive layer disposed above the second patterned conductive layer and adapted to be electrically connected to ground; and
a plurality of insulating layers respectively disposed between two adjacent conductive layers.

18. The electronic apparatus according to claim 17, wherein the FPC has a universal system bus (USB) region, and the first patterned conductive layer comprises:
a plurality of first signal traces disposed within the USB region; and
two ground guarding traces respectively disposed at two opposite sides of the USB region, the ground guarding traces are adapted to be electrically connected to ground, wherein the second patterned conductive layer has no conductive trace overlapping the first signal traces within the USB region.

19. The electronic apparatus according to claim 17, wherein the FPC has a video signal region, and the first patterned conductive layer comprises:
a plurality of second signal traces disposed within the video signal region; and
two first ground guarding traces respectively disposed at two opposite sides of the video signal region, and
the second patterned conductive layer comprises a second ground guarding trace, wherein orthogonal projections of the second signal traces on the second patterned conductive layer are located within the second ground guarding trace.

20. The electronic apparatus according to claim 17, wherein the first patterned conductive layer comprises a plurality of first signal traces, the second patterned conductive layer comprises a plurality of second signal traces, and the first signal traces do not overlap the second signal traces.
